(19) United States
(12) Patent Application Publication
(10) Pub. No.: US 2016/0190382 A1
(43) Pub. Date: Jun. 30, 2016

(54) AMORPHOUS SILICON BASED LASER DOPED SOLAR CELLS

(71) Applicant: Solexel, Inc., Milpitas, CA (US)

(72) Inventor: Pawan Kapur, Burlingame, CA (US)

(21) Appl. No.: 14/825,163

(22) Filed: Aug. 12, 2015

Related U.S. Application Data
(60) Provisional application No. 62/036,609, filed on Aug. 12, 2014.

(51) Int. Cl. H01L 31/18; H01L 31/0376

(52) U.S. Cl. CPC H01L 31/1864; H01L 31/1804; H01L 31/03762

(57) ABSTRACT

A passivated surface and base and emitter regions in a silicon substrate are formed. Intrinsic amorphous silicon is formed on first surface of a silicon substrate. A first dopant is formed on the intrinsic amorphous silicon. A first laser beam is applied through the first dopant and forms a first doped region in the silicon substrate. A second dopant is formed on the intrinsic amorphous silicon. A second laser beam is applied through the second dopant and forms a second doped region in the silicon substrate.

### CROSS-REFERENCE TO RELATED APPLICATIONS

This application claims the benefit of U.S. provisional patent application 62/036,609 filed on Aug. 12, 2014, which is hereby incorporated by reference in its entirety.

### FIELD OF THE INVENTION

The present disclosure relates in general to the fields of solar cells, and more particularly to solar cell doped regions.

### BACKGROUND

As solar photovoltaic technology is adopted as an energy generation solution on an increasingly widespread scale, improvements relating to solar cell efficiency and fabrication are required. Generally, solar cell structures often include passivation surfaces—for example frontside or light receiving (sunnyside) surface passivation and backside surface passivation opposite the frontside. Surface passivation and doped base and emitter formation processes are often complex and employ mechanically or thermally stressful processing.

Additionally, manufacturing cost and conversion efficiency factors are driving solar cell semiconductor absorbers ever thinner in thickness and larger in area. Thin semiconductor absorbers and corresponding thin semiconductor absorber solar cell structure aspects/components have increased fragility and are more sensitive to temperature and mechanical processing, thus, complicating and introducing challenges in the processing of these thin absorber based solar cells.

### BRIEF SUMMARY OF THE INVENTION

Therefore, a need has arisen to go to the highest possible efficiency which can be attained using best possible passivation, while keeping lowest possible temperatures, reducing the complexity of integration, and reducing the capital expenditure for manufacturing. In accordance with the disclosed subject matter, surface passivation and doped base and emitter formation processes are provided which may substantially eliminate or reduce disadvantage and deficiencies associated with previously developed good surface passivation but highly complex and capital intensive manufacturing methods.

According to one aspect of the disclosed subject matter, a method for passivating a silicon surface and forming doped base and emitter regions in a silicon substrate is provided. Intrinsic amorphous silicon is formed on first surface of a silicon substrate. A first doped layer is formed on the intrinsic amorphous silicon. A first laser beam is applied through the first dopant and forms a first doped region in the silicon substrate. A second dopant is formed on the intrinsic amorphous silicon. A second laser beam is applied through the second dopant and forms a second doped region in the silicon substrate.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1A is a cross-sectional diagram showing a simplified depiction of an amorphous silicon laser doped solar cell after partial backside processing and highlighting passivation films and dopings;

FIG. 1B is a cross-sectional diagram showing a simplified depiction of the amorphous silicon laser doped solar cell of FIG. 1A after additional backside processing;

FIG. 2 is a top view diagram showing a simplified depiction of the backside of an amorphous silicon laser doped solar cell after laser doping;

FIGS. 3A through 3E are cross-sectional diagrams showing a simplified depiction of an amorphous silicon laser doped solar cell after the partial backside processing steps; and

FIGS. 4A through 4D are cross-sectional diagrams showing a simplified depiction of an amorphous silicon laser doped solar cell after the partial backside processing steps.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like aspects and identifiers being used to refer to like and corresponding parts of the various drawings.

And although the present disclosure is described with reference to specific embodiments and components, such as a back contact back junction (BCBJ) silicon solar cell, one skilled in the art could apply the principles discussed herein to other solar cell structures (e.g., front contact or back contact front junction), fabrication processes (e.g., various deposition methods and materials such as metallization materials), as well as alternative technical areas and/or embodiments without undue experimentation.

Fabrication methods and structures are provided for the doping and passivation of solar cells. High efficiency silicon based solar cell structures and their manufacturing methods are characterized by a passivation of hydrogenated amorphous silicon or a variant produced by adding small quantities of carbon (SiCx), oxygen (SiOx), or nitrogen (SiNx), as a passivation followed by laser doping of a dopant to make diffused junctions. Note, as described herein, amorphous silicon should also be interpreted more generally to include SiOx and SiCx and SiNx variants and embodiments.

The solar cells described herein are back contact cells, however, the innovations provided herein may also be adopted for front contact solar cells. The solar cells described herein may be thin solar cells for example having a silicon absorber layer thickness in the range of 5 μm to 120 μm. Thin solar cells may be manufactured using the backplane embodiments are provided. However, the passivation and doping fabrication methods and structure should not be interpreted in a limiting sense and are applicable to thicker (e.g., thicker than 120 μm) and thinner solar cells.

While the exemplary solar cells provided use n-type starting substrates, the innovations provided herein including passivation and doping are applicable to p-type starting substrates and the flow sequence and base/emitter may be modified appropriately.

Additionally, although the solar cells described herein are single crystal solar cells, for example because of low temperature processing, the cell designs and manufacturing methods are also applicable for multi-crystalline solar cells. For multi-crystalline solar cells for example, at the fabrication onset a high temperature gettering step may be performed to increase lifetime. N-type multi-crystalline substrates in excess of 500 us are possible after gettering. Subsequently, using the fabrication processes provided the temperature of the cell is always kept relatively low (e.g. less than 350° C.), thus maintaining the lifetime which was achieved after the gettering at the onset. This is especially attractive when the multi-crystalline cell is also thinner as well as manufactured with low temperature processes which may lead to a very high efficiency multi-crystalline solar cell. In addition to multi-crystalline solar cells, the manufacturing flows and structures in this document can also be applied to epitaxially grown silicon solar cells.

Unlike a traditional silicon heterojunction solar cells which are made with amorphous silicon passivation, the amorphous silicon layer (and its variants) as provided herein is not necessarily a transport layer because of the presence of diffused junction. And while, as provided herein, hydrogenated amorphous silicon (and its variants) is a superior passivation, hydrogenated amorphous silicon (and its variants) may also be the dopant source for laser doping. This may be especially advantageous as during laser doping both amorphous silicon as well as the underlying crystalline silicon layer, to a controlled depth, are melted which, in turn, results in a high dopant solubility—thus, achieving localized doping where the laser hits the wafer without raising the temperature of the whole silicon wafer, which may preserve high quality passivation as well as bulk wafer lifetime Upon cooling and ensuing re-crystallization, the silicon is not only doped (as diffusion starts at the surface) but the contact is accessible at the surface—thus a self-aligned contact with a doped area conductive and available for contact—while areas which did not see laser remain insulating.

It is to be understood that hydrogenated amorphous silicon a-Si as a layer or film, as described herein, may also be variants of a-Si film as is common in the technical area such as amorphous SiCx, amorphous SiOx, and amorphous SiNx. Variant layers or films may include but are not limited to amorphous hydrogenated SiCx, SiOx, SiNx. In these films a small amount of carbon, oxygen, and nitrogen may be introduced, respectively. Amorphous silicon and its variants may retain high passivation quantity, may be made both n and p-type, may help increase the bandgap depending on the concentration, and in certain cases may help improve thermal stability at higher temperatures (e.g., greater than 300° C.).

The solar cell structures provided herein may retain advantages of high efficiency silicon heterojunction solar cells without processing related drawbacks. For example, the solar cell structures provided may have some or all of the following advantages: capable of very high efficiency, for example approaching 26%, especially when integrated with the back contacted architecture; do not have high temperature processing steps (e.g., no greater than 400° C.) thus maintaining the pristine lifetime of the initial substrate; retain high temperature coefficient of efficiency, for example typically less than −0.3% /C.

Additionally, as compare to silicon heterojunction solar cells, the manufacturing methods provided herein may be robust and have reduced complexity. For example, manufacturing methods provided may have some or all of the following advantages: a solar cell fill factor FF independent of the thickness of the amorphous silicon, for example because the FF is controlled by the laser doped contact, which relaxes and/or removes thickness constraints of the amorphous silicon (traditionally amorphous silicon thickness constraints have made silicon heterojunction solar cells in general and back contacted silicon heterojunction solar cells plagued by narrow process windows and FF problems); capital expenditures reduction, for example in certain fabrication embodiments provided herein only one PECVD and PVD tool is required; ITO and Ag PVD (relatively expensive materials) are not required; because of lack of full area emitter, the parasitic free carrier absorption is mitigated; and, simplified process flows are provided. Additionally, the fabrication processes provided herein may withstand higher temperatures (e.g., above 300° C.) without degrading performance. In other words, as is known in the art, it may be difficult to increase the temperature of a device having p+ amorphous silicon above 250° C. without degrading its passivation quality, while intrinsic and n+ amorphous silicon layers are more thermally stable up to about 350° C.—in several fabrication process flows provided herein, the solar cells does not require p+ amorphous silicon, thus enabling it to withstand and maintain high quality passivation up to higher temperature (e.g., up to approximately 375° C.).

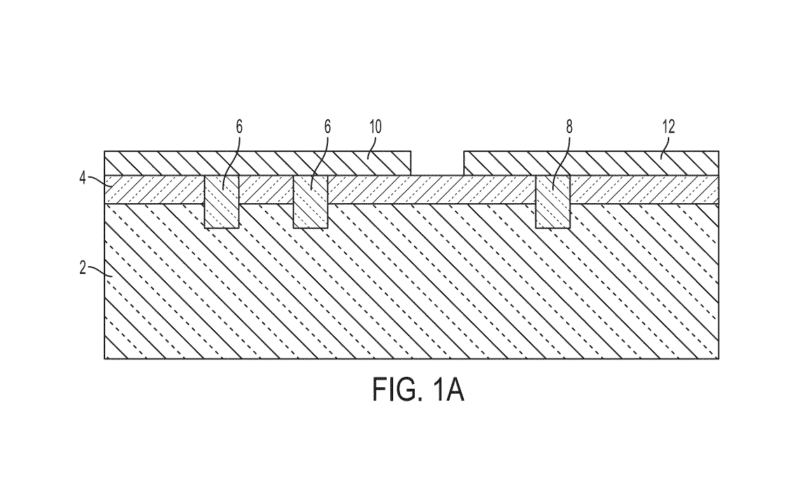

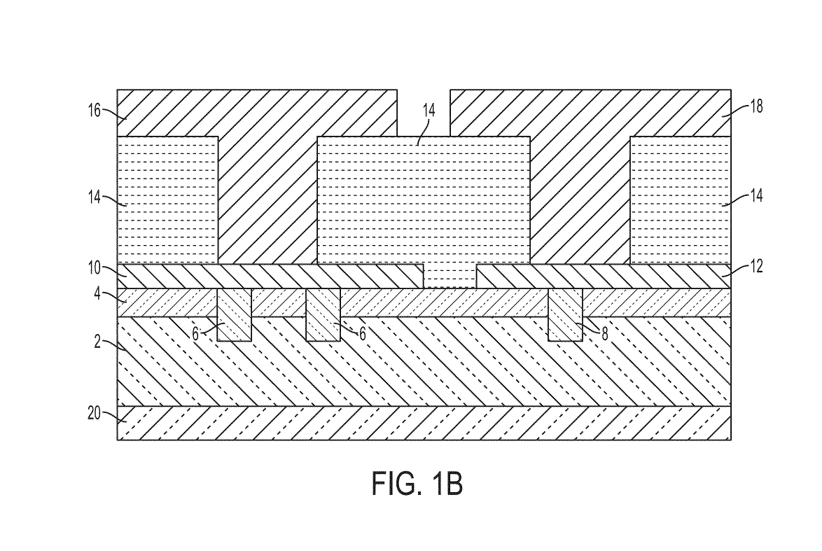

FIG. 1A is a cross-sectional diagram showing a simplified depiction of an amorphous silicon laser doped solar cell after partial backside processing and highlighting passivation films and dopings. Amorphous silicon passivation 4 is positioned on n-type silicon substrate 2. P+ doped regions 6 and n+ doped regions 8 are formed in silicon substrate 2. Cell emitter metal 10 is positioned on and p+ doped regions 6 and cell base metal 12 is positioned on n+ doped regions 8. Cell emitter and base metallization may be conductive metals such as, for example, aluminum or copper. Solar cell structure embodiments may have different shapes, doping region structure, and film topographies. The solar cell of FIG. 1A may be a partially processed solar cell structure or a cell having a standard thickness (e.g., having a thickness greater than 140 μm).

FIG. 1B is a cross-sectional diagram showing a simplified depiction of the amorphous silicon laser doped solar cell of FIG. 1A after additional backside processing. Backplane 14 is attached to the solar cell backside, for example as shown in FIG. 1B backplane 14 attachment to cell base metal 12 and cell emitter metal 10, and amorphous silicon passivation 4. Second emitter metal 16 and second base metal 18 contact cell emitter metal 10 and cell base metal 12, respectively, through vias in backplane 14. The frontside (also called the sunnyside) of the solar cell is textured and passivated, shown in FIG. 1B as frontside texture and passivation 20 on n-type silicon substrate 2. Second emitter and base metallization may be conductive metals such as, for example, aluminum or copper. Backplane 14 may be an electrically insulating material, for example such as prepreg. The solar cell structure shown in FIG. 1B, including a supporting backplane and dual level metallization, provides mechanical support for a finished thin silicon solar cell having a silicon thickness (for example n-type silicon substrate 2 as shown in FIGS. 1A and 1B) of less than 120 μm (e.g., a silicon thickness in the range of 10 to 120 μm.

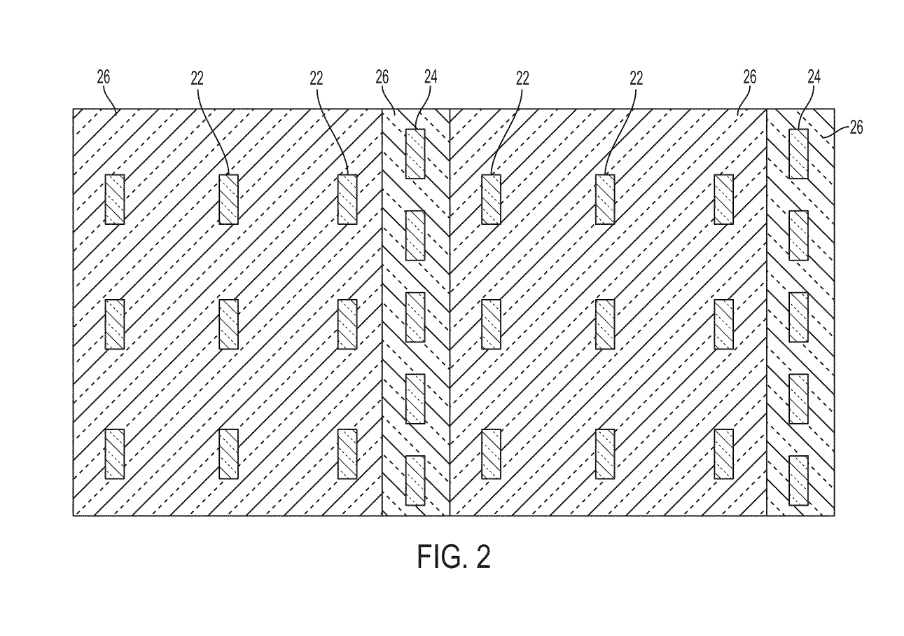

FIG. 2 is a top view diagram showing a simplified depiction of the backside of an amorphous silicon laser doped solar cell after laser doping. Emitter doped islands 22 are laser doped emitter regions, for example doped with boron for an n-type silicon substrate. The non-doped backside surface is covered with amorphous silicon passivation 26 (amorphous silicon passivation 26 covers the entire backside surface although base and emitter regions identified visually in FIG. 2 with differing amorphous silicon cross-hatching for descriptive purposes). Base doped islands 24 are laser doped base regions, for example doped with phosphorous for an n-type silicon substrate. The total contact area fraction (i.e., the laser doped areas) may be kept low to achieve a high Voc. Laser beam parameters for laser doping may be adjusted and optimized such that the laser goes through dopant source and heats to melting the underlying silicon substrate to pull the overlying dopant into the silicon substrate at a predetermined depth. Laser parameters include green, IR, or UV wavelengths and green wavelength may be particularly advantageous for heating underlying silicon.

Aspects of the solar cell provided herein may include, for example: no continuous emitter, so the point contacts in the form of p+ doping (e.g., for n-type substrate solar cell) should be spaced closed enough together such that there is minimal or no series resistance issues and minimal or no minority carrier lifetime issues; bulk lifetime and surface passivation (frontside passivation and backside passivation) should be high enough quality such that minority carriers (holes in the case of n-type substrate solar cells) may survive longer distances (e.g., with a bulk lifetime of 1.5 ms and relatively thicker hydrogenated a-Si, the surface recombination velocities can be as low as less than 5 cm/s); the thickness of a-Si may be in a much higher range (e.g., 10-300 nm) than the existing silicon heterojunction solar cells as the solar cell structure does not rely on this layer for current transport; in several embodiments, the emitter does not consist of a P+/intrinsic (i) amorphous silicon layer, but a diffused emitter P+ contact connecting to a metal which is otherwise insulated from the main substrate.

Solar cell backside fabrication process flows are provided which may be used to form point contacted back contact back junction solar cells having a thicker silicon thickness (e.g., a solar cell silicon substrate thickness greater than 140 μm) or may be coupled with various backend process flows including those for the formation of a solar cell utilizing a backplane (e.g., a prepreg backplane) to form a point contacted back contact back junction solar cell having a thinner silicon thickness (e.g., a solar cell silicon substrate thickness less than 120 μm). Various process flow options are provided which use depositing metal (e.g., physical vapor deposition PVD) and patterning for the cell base and emitter metallization. For example, metal patterning may be performed using laser processing—green, UV or IR nanosecond or picosecond pulsed laser may be used. Shorter wavelengths may have the advantage of being absorbed in amorphous silicon to ensure that there is minimal damage to the underlying crystalline silicon and thus retention of high lifetime. Metal patterning may also be performed using process such as: screen print resist and wet etch; metal etch paste; and print resist, laser patter resist, and wet etch of metal. These embodiments and others are implicit in the following process tables.

The following tables are provided as descriptive process flow examples for making laser doped, amorphous silicon point contacted solar cells and should not be interpreted in the limiting sense. Fabrication steps are abbreviated as follows: saw damage removal SDR; spin-on doping SOD; plasma enhanced chemical vapor deposition PECVD; physical vapor deposition PVD.

Tables 1A through 6A are distinguished by the types of dopant sources that are used for laser doping for both p and n-type doping. For example, Tables 1A and 2A use n+ doped amorphous silicon as a dopant source, Tables 3A and 4A use phosphorous or other n+ doped spin on dopants (SODs), and Tables 5A and 6A use patterned dopant sources such as a screen printed n+ phosphorous layer. For each of these base or n+ doped options, there are either spin on dopant (SOD) or patterned dopant options for p+ (boron doping). Tables 1A through 6A use metal PVD followed by patterning to create cell base and emitter metal.

TABLE 1A
n+ dopant source is a-Si, p+ dopant
source is SOD, metal PVD deposition

| | |
|---|---|
| 1 | SDR |
| 2 | PECVD intrinsic (10 nm-100 nm) + n+ |
| | (10 nm-100 nm) amorphous silicon |
| 3 | Emitter window open to etch n+ layer |
| | (stop inside the intrinsic layer) |
| 4 | Spin on boron dopant |
| 5 | Laser dope emitter |
| 6 | Remove dopant source |
| 7 | Laser dope base |
| 8 | PVD metal (e.g., Ni/Al, Ti/Al, Al, Ag, others) |
| 9 | Metal definition |
| 10 | Screen print pads |

TABLE 2A
n+ dopant source is a-Si, p+ dopant
source is screen print paste, metal PVD

| | |
|---|---|
| 1 | SDR |
| 2 | PECVD intrinsic (10 nm-100 nm) + n+ |
| | (10 nm-100 nm) amorphous silicon |
| 3 | Emitter window open to etch n+ layer |
| | (stop inside the intrinsic layer) |
| 4 | Screen print or inkjet patterned boron doping source |
| 5 | Laser dope emitter and base |
| 6 | Remove dopant source |
| 7 | PVD metal (ex. Ni/Al, Ti/Al, Al, Ag, others) |
| 8 | Metal definition |
| 9 | Screen print pads |

TABLE 3A
n+ is SOD, p+ is SOD, metal PVD

| | |
|---|---|
| 1 | SDR |
| 2 | PECVD intrinsic hydrogenated amorphous silicon (10 nm-100 nm) |
| 3 | SOD spin on phosphorous dopant |
| 4 | Laser dope base |
| 5 | Remove dopant source |
| 6 | SOD spin on boron dopant |
| 7 | laser dope emitter |
| 8 | Remove dopant source |
| 9 | PVD metal (ex. Ni/Al, Ti/Al, Al, Ag, others) |
| 10 | Metal definition |
| 11 | Screen print pads |

TABLE 4A
n+ is SOD, p+ is patterned screen print/inkjet, metal PVD

| | |
|---|---|
| 1 | SDR |
| 2 | PECVD intrinsic hydrogenated amorphous silicon (10 nm-100 nm) |
| 3 | SOD spin on phosphorous dopant |
| 4 | Laser dope base |
| 5 | Remove dopant source |
| 6 | Screen print or inkjet patterned boron dopant source |
| 7 | laser dope emitter |
| 8 | Remove dopant source |
| 9 | PVD metal (ex. Ni/Al, Ti/Al, Al, Ag, others) |
| 10 | Metal definition |
| 11 | Screen print pads |

TABLE 5A
n+ and p+ are patterned inkjet/screen print, metal PVD

| | |
|---|---|
| 1 | SDR |
| 2 | PECVD intrinsic hydrogenated amorphous silicon (10 nm-100 nm) |
| 3 | Screen print/inkjet pattered boron and phosphorous pastes |
| 4 | Laser dope both base and emitter |
| 5 | Remove dopant source |
| 6 | PVD Metal (ex. Ni/Al, Ti/Al, Al, Ag, others) |
| 7 | Metal definition |
| 8 | Screen print pads |

TABLE 6A
n+ is patterned inkjet/screen print, p+ is SOD, metal PVD

| | |
|---|---|
| 1 | SDR |
| 2 | PECVD intrinsic hydrogenated amorphous silicon (10 nm-100 nm) |
| 3 | Screen print/inkjet or any patterned dopant source |
| 4 | Laser dope base |
| 5 | Remove Dopant source |
| 6 | SOD spin on Boron dopant |
| 7 | laser dope emitter |
| 8 | Remove Dopant source |
| 9 | PVD Metal (ex. Ni/Al, Ti/Al, Al, Ag, others) |
| 10 | Metal definition |
| 11 | Screen print pads |

Tables 1B through 6B are distinguished by the types of dopant sources that are used for laser doping for both p and n-type doping. Tables 1B through 6B are similar to Tables 1A through 6A. For example, Tables 1 and 2 use n+ doped amorphous silicon as a dopant source, Tables 3 and 4 use phosphorous or other n+ doped spin on dopants (SODs), and Tables 5 and 6 use patterned dopant sources such as a screen printed n+ phosphorous layer. For each of these base or n+ doped options, there are either spin on dopant (SOD) or patterned dopant options for p+ (boron doping). Tables 1B through 6B use patterned metal (e.g., formed using screen print or inkjet processes) to create cell base and emitter metal. Alternatively a combination of PVD and patterned metal techniques and accompanying variants may also form cell and base emitter metal.

TABLE 1B
n+ dopant source is a-Si, p+ dopant
source is SOD, metal screen print/inkjet

| | |
|---|---|
| 1 | SDR |
| 2 | PECVD intrinsic (10 nm-100 nm) + n+ |
| | (10 nm-100 nm) amorphous silicon |
| 3 | Emitter window open to etch n+ layer |
| | (stop inside the intrinsic layer) |
| 4 | Spin on boron dopant |
| 5 | Laser dope emitter |
| 6 | Remove dopant source |
| 7 | Laser dope Base |
| 8 | Screen print/inkjet patterned metal: |
| | Al paste, NI inks + paste |

TABLE 2B
n+ dopant source is a-Si, p+ dopant source is
screen print/inket, metal screen print/inkjet

| | |
|---|---|
| 1 | SDR |
| 2 | PECVD intrinsic (10 nm-100 nm) + n+ |
| | (10-100 nm) amorphous silicon |
| 3 | Emitter window open to etch n+ layer |
| | (stop inside the intrinsic layer) |
| 4 | Screen print or inkjet patterned Boron doping source |
| 5 | Laser dope emitter and base |
| 6 | Remove Dopant source |
| 7 | Screen print/inkjet patterned metal + pads: |
| | Al paste, NI inks + paste |

TABLE 3B
n+ is SOD, and p+ is SOD, metal patterned (screen print, inkjet)

| | |
|---|---|
| 1 | SDR |
| 2 | PECVD intrinsic hydrogenated amorphous silicon (10 nm-100 nm) |
| 3 | SOD spin on phosphorous dopant |
| 4 | Laser dope base |
| 5 | Remove dopant source |
| 6 | SOD spin on boron dopant |
| 7 | laser dope emitter |
| 8 | Remove dopant source |
| 9 | Screen print/inkjet patterned metal + pads: Al paste, NI inks + paste |

TABLE 4B
n+ is SOD, p+ is patterned screen print/inkjet,
metal patterned (screen print/inkjet)

| | |
|---|---|
| 1 | SDR |
| 2 | PECVD intrinsic hydrogenated amorphous silicon (10 nm-100 nm) |
| 3 | SOD spin on phosphorous dopant |
| 4 | Laser dope base |
| 5 | Remove dopant source |
| 6 | Screen print boron dopant source |
| 7 | laser dope emitter |
| 8 | Remove dopant source |
| 9 | Screen print/inkjet patterned metal + pads: Al paste, NI inks + paste |

TABLE 5B
n+ and p+ are patterned inkjet/screen print,
metal: patterned (screen print/inkjet)

| | |
|---|---|
| 1 | SDR |
| 2 | PECVD intrinsic hydrogenated amorphous silicon (10 nm-100 nm) |
| 3 | Screen print/inkjet pattered boron and phosphorous pastes |
| 4 | Laser dope both base and emitter |
| 5 | Remove dopant source |
| 6 | Screen print/inkjet patterned metal + pads: Al paste, NI inks + paste |

TABLE 6B
n+ is patterned inkjet/screen print, p+ is
SOD, metal patterned (screen print/inkjet)

| | |
|---|---|
| 1 | SDR |
| 2 | PECVD intrinsic hydrogenated amorphous silicon (10 nm-100 nm) |
| 3 | Screen print/inkjet or any patterned dopant source |
| 4 | Laser dope base |
| 5 | Remove dopant source |
| 6 | SOD spin on boron dopant |
| 7 | laser dope emitter |
| 8 | Remove dopant source |
| 9 | Screen print/inkjet patterned metal + pads: Al paste, NI inks + paste |

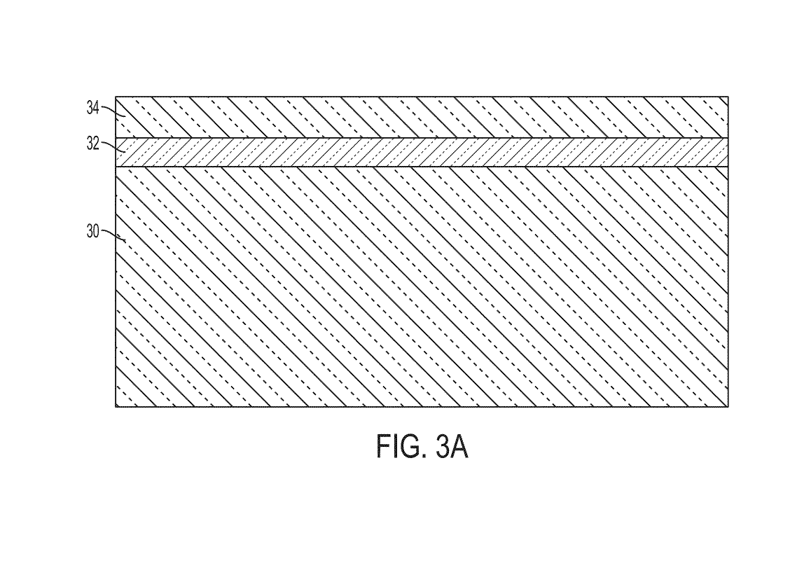

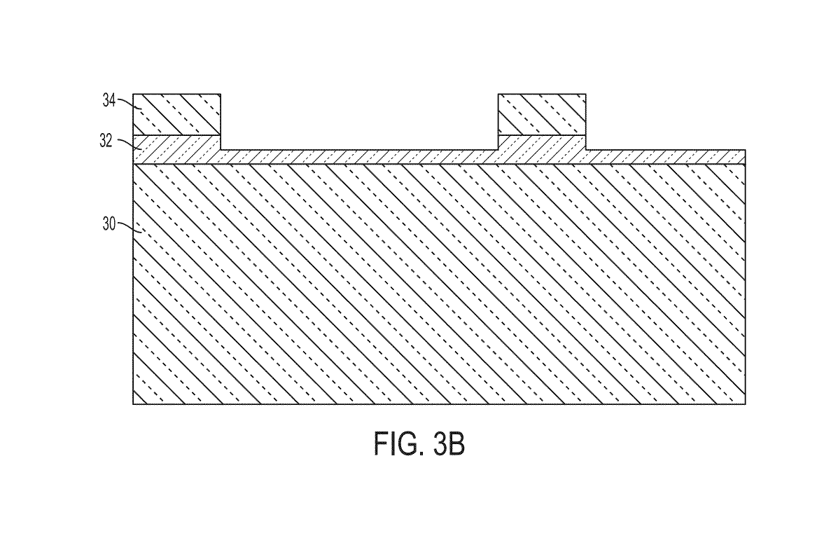

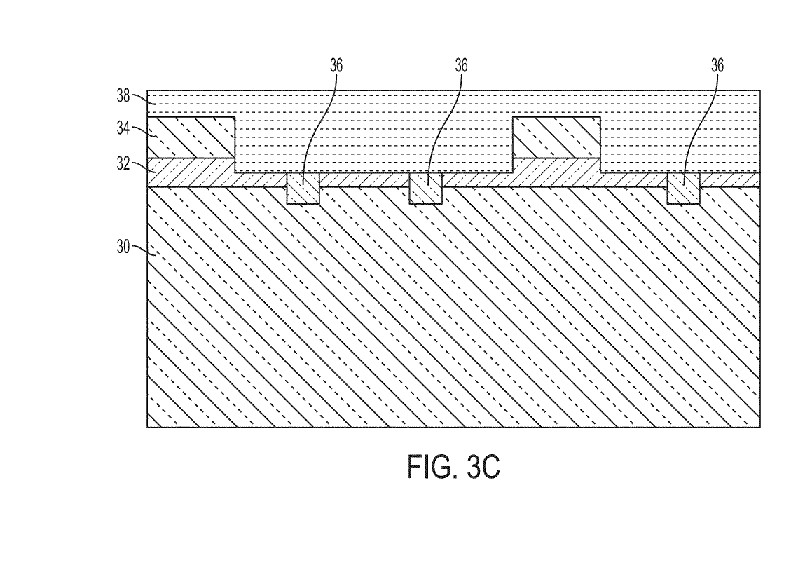

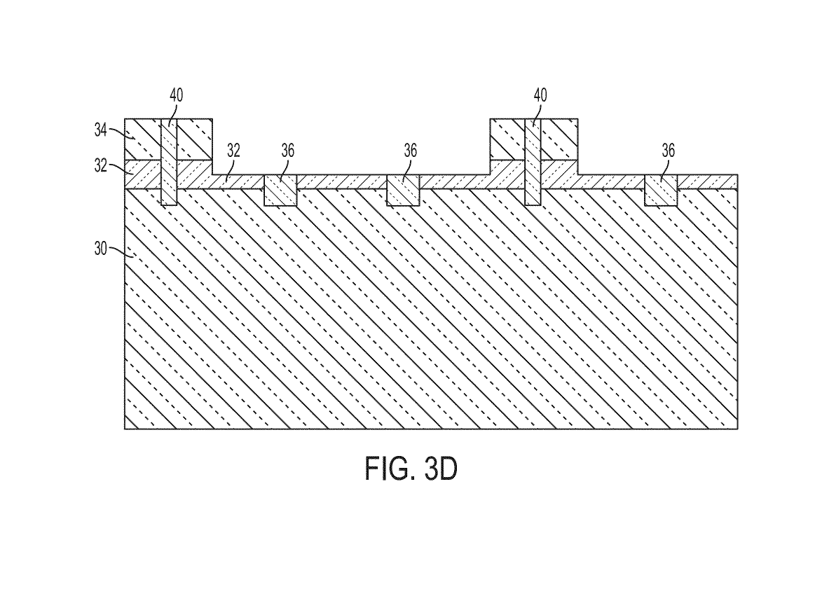

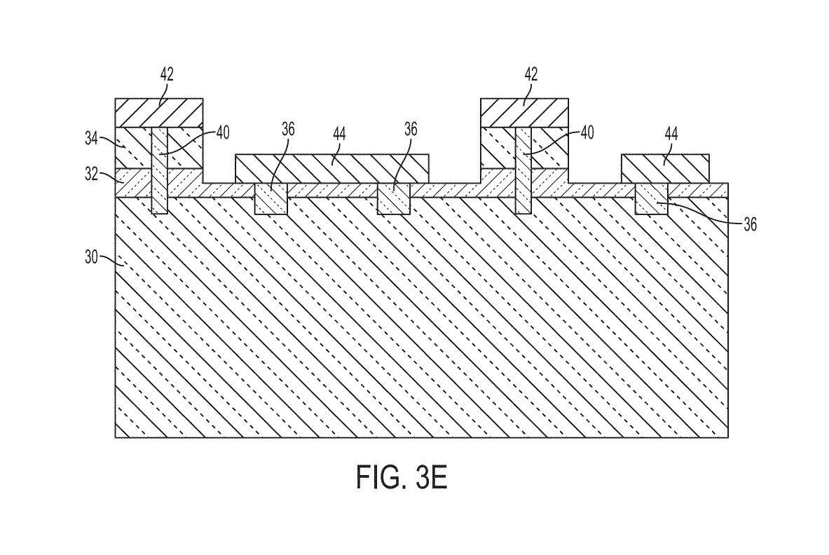

FIGS. 3A through 3E are cross-sectional diagrams showing a simplified depiction of an amorphous silicon laser doped solar cell after the partial backside processing steps shown in Tables 1A and 1B and using n+ doped amorphous silicon as a dopant source. FIG. 3A corresponds to Step 2 in Tables 1A and 1B of thick intrinsic amorphous silicon and n+ amorphous silicon PECVD deposition. Intrinsic amorphous silicon 32 is on n-type silicon substrate 30. N+ amorphous silicon 34 is on intrinsic amorphous silicon 32.

FIG. 3B corresponds to Step 3 in Tables 1A and 1B of patterned emitter window opening and etch. FIG. 3C corresponds to Steps 4 and 5 in Tables 1A and 1B of spin on boron dopant SOD and laser doping of emitter through SOD. Spin on boron dopant 38 is formed on intrinsic amorphous silicon 32 (and n+ amorphous silicon 34). P+ emitter doped regions 36 are formed by applying laser through spin on boron dopant 38 to silicon substrate 30 to form p+ emitter doped regions 36 through intrinsic amorphous silicon 32. FIG. 3D corresponds to Steps 5 and 6 in Tables 1A and 1B of SOD removal and laser doping using n+ amorphous silicon. Spin on boron dopant 38 is removed. N+ base doped regions 40 are formed by applying laser through n+ amorphous silicon 34 to silicon substrate 30 to form n+ base doped regions 40 through intrinsic amorphous silicon 32.

FIG. 3E corresponds to Steps 7 and/or 8 in Tables 1A and 1B of cell base and emitter metallization of metal PVD plus patterning (as described in Table 1A) or patterned metal deposition using screen print or inkjet (as described in Table 1B). Cell base metallization 42 is formed on n+ base doping regions 40 and cell emitter metallization 44 is formed on p+ emitter doped regions 36.

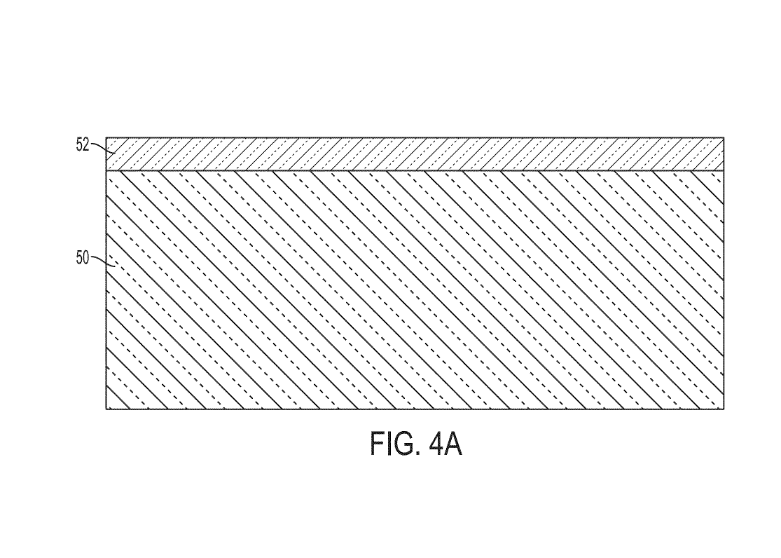

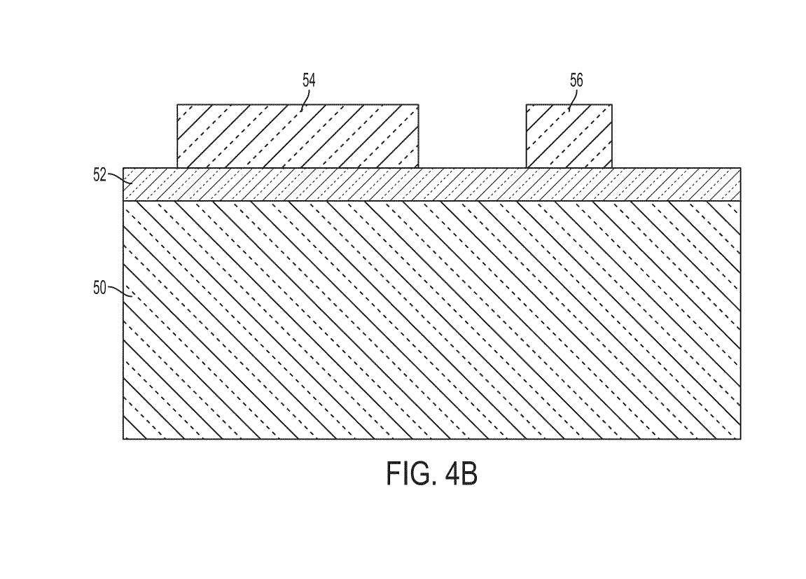

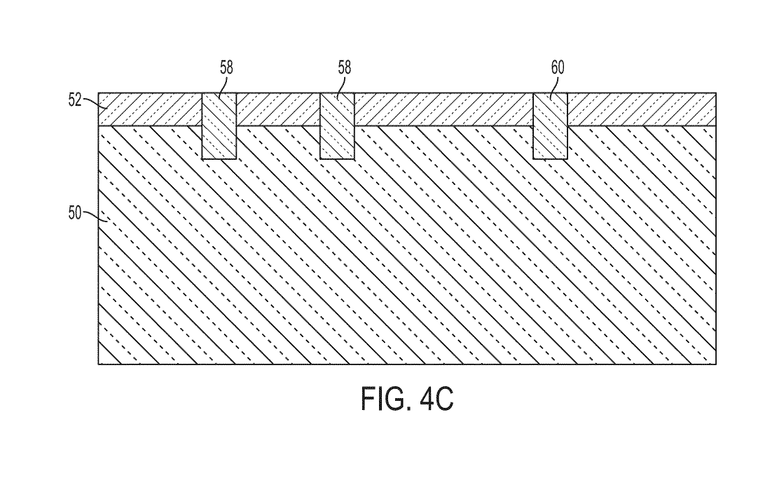

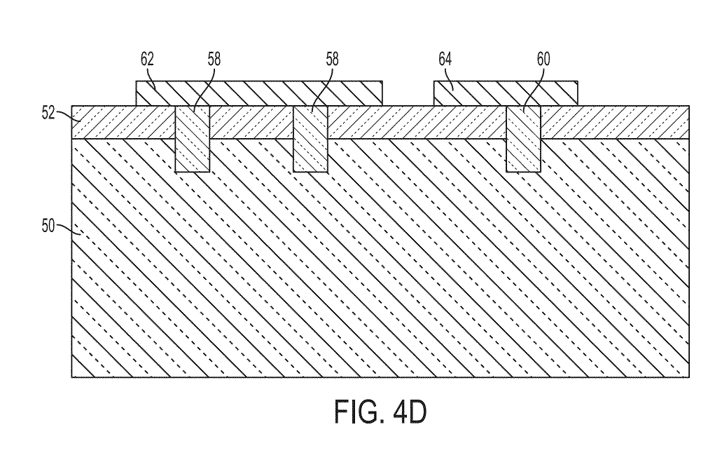

FIGS. 4A through 4D are cross-sectional diagrams showing a simplified depiction of an amorphous silicon laser doped solar cell after the partial backside processing steps shown in Tables 5A and 5B and using patterned dopant sources such as screen printed phosphorous doping. FIG. 4A corresponds to Step 2 in Tables 5A and 5B of thick intrinsic amorphous silicon PECVD deposition. Intrinsic amorphous silicon 52 is on n-type silicon substrate 50.

FIG. 4B corresponds to Step 3 in Tables 5A and 5B of forming a patterned dopant source on intrinsic amorphous silicon 52, for example a p-type dopant source print and an n-type dopant source print using screen printing. P-type dopant source 54 and n-type dopant source 56 are formed on intrinsic amorphous silicon 52. FIG. 4C corresponds to Steps 4 and 5 in Tables 5A and 5B of laser doped p+ and n+ regions and dopant source removal. P+ doped regions 58 are formed by applying laser through p-type dopant source 54 to silicon substrate 50 to form p+ doped regions 58 through intrinsic amorphous silicon 52. N+ doped regions 60 are formed by applying laser through n-type dopant source 56 to silicon substrate 50 to form n+ doped regions 60 through intrinsic amorphous silicon 52. P-type dopant source 54 and n-type dopant source 56 are removed.

FIG. 4D corresponds to Steps 6 and/or 7 in Tables 5A and 5B of cell base and emitter metallization of metal PVD plus patterning (as described in Table 5A) or patterned metal deposition using screen print or inkjet (as described in Table 5B). Cell base metallization 64 is formed on n+ base doping regions 60 and cell emitter metallization 62 is formed on p+ emitter doped regions 58.

Alternatively, another source of p+ doping may be a boron doped PECVD deposited amorphous silicon layer. P+ doping using a boron doped PECVD deposited amorphous silicon layer may be combined with various kinds of phosphorous doped n+ sources (e.g., as provided herein). Tables 7A and 7B below show descriptive process flow examples for making laser doped, amorphous silicon point contacted solar cells example where p+ amorphous silicon and n+ amorphous silicon layers are used as dopant sources. Tables 7A and 7B may be modified to dope using both n+ and p+ amorphous silicon in laser processes on top of each other and relying on counterdoping to do both base and emitter dopings simultaneously—for example by adjusting the thicknesses of the doping layers. Table 7A uses metal PVD followed by patterning to create cell base and emitter metal. Table 7B uses patterned metal (e.g., formed using screen print or inkjet processes) to create cell base and emitter metal.

TABLE 7A
n+ is a-Si, p+ is a-Si, metal PVD

| | |
|---|---|
| 1 | SDR |
| 2 | PECVD intrinsic (10 nm-100 nm) + n+ |
| | (10 nm-100 nm) amorphous silicon |
| 3 | Emitter window open to etch n+ layer |
| | (stop inside the intrinsic layer) |
| 4 | PECVD p+ amorphous silicon (Example: 10-100 nm) |
| 5 | Open base contact, Etch away p+ layer i |
| 6 | Laser dope emitter and base |
| 7 | PVD metal (ex. Ni/Al, Ti/Al, Al, Ag, others) |
| 8 | Metal definition |
| 9 | Screen print pads |

TABLE 7B
n+ is a-Si, p+ is a-Si, metal is patterned metal (screen print/inkjet)

| | |
|---|---|
| 1 | SDR |
| 2 | PECVD intrinsic (10 nm-100 nm) + n+ |
| | (10 nm-100 nm) amorphous silicon |
| 3 | Emitter window open to etch n+ layer |
| | (stop inside the intrinsic layer) |
| 4 | PECVD p+ amorphous silicon (Example: 10-100 nm) |
| 5 | Open base contact, Etch away p+ layer i |
| 6 | Laser dope emitter and base |
| 7 | Screen print/inkjet patterned metal + pads: |
| | Al paste, NI inks + paste |

Alternatively, the p+ dopant source may be aluminum metal. A technique such as laser fired contact through either a PVD AL or Al paste may be used in conjunction with the fabrication methods provided.

The solar cell structures provided have a very high efficiency potential as long as the contact area is kept low/minimal for both n and p-type contacts. Thus, a contact resistivity of less than 1 e-3 may be required and in some instances a contact resistivity more particularly in the range of less than 1 e-4 ohm-cm2. With diffused contacts, it is possible to get Jo contact (dark saturation current density under the contact area to be in 800-1200 fA/cm2). With 1% contact area, the total Jo from both contacts may be kept to less than 20 fA/cm2. With bulk lifetime and cells being thin, the bulk Jo and base Jo may be as low as less than 10 fA/cm2, while the backside thick amorphous silicon passivation is capable of less than 5 fA/cm2 Jo. Combining this may reveal a total Voc potential of greater than 730 mV.

While all the devices discussed above may be considered a class of devices where the carrier transport and photocurrent collection is done using diffused n+ and p+ layers, it is also possible to have devices where the thickness of the amorphous silicon layer is reduced to use it for partial carrier transport in conjunction with the diffused layers—in other words a hybrid device. A hybrid device may explicitly require a p+ amorphous silicon layer as the emitter along with a P+ laser doped contact. Hybrid devices may be especially applicable to cases using SiOx and SiCx where the bandgap is larger than pure amorphous silicon and hence the transport may not be adequate. In such cases, the transport may be supplemented using the diffused contacts.

Key factors increasing the solar cell efficiency of the structures provided is that, in at least in one embodiment they are: back contacted; silicon heterojunction solar cells like without suffering from the process complexities of silicon heterojunction solar cells and silicon heterojunction solar cell fabrication; and may be made ultrathin, for example having a silicon thickness as thin as 10 μm providing 800 mV Voc potential.

As noted, cell efficiency may be enhanced by and particularly advantageous when combining the passivation and doping innovations provided herein with silicon absorber thickness reduction—for example having a thickness less than 120 μm and, for practical purposes, a thickness greater than 5 μm. Thin silicon absorbers benefit from mechanical backplane support and decoupling of thermal stresses, such as for example the supportive backplane and multi-level cell metallization of the solar cell of FIG. 1B. Patent applications providing relevant information relating to solar cells structures having a backplane and multi-level metallization include U.S. Pat. Pub. 2013/0213469 published Aug. 22, 2013, 2013/0228221 published Sep. 5, 2013, and 2014/0370650 published Dec. 18, 2014, all of which are hereby incorporated by reference in their entirety.

A thin silicon absorber based solar cell (e.g., having a silicon absorber thickness less than 120 μm) may utilize: a prepreg supporting backplane; an etch back step to thin down the wafer; monolithic isle (icell) cut technology (e.g., such as that found in U.S. Pat. Pub. 2014/0370650 published Dec. 18, 2014); and an aluminum oxide based front passivation (e.g., such as that found in U.S. Pat. Pub. 2015/0162487 published Jun. 11, 2015 which is hereby incorporated by reference in its entirety and U.S. patent Ser. No. 14/632,696 filed Feb. 26, 2015 which is hereby incorporated by reference in its entirety). Table 8 below shows a descriptive process flow example for making laser doped, amorphous silicon point contacted solar cells having a backplane and multi-level metallization structure.

TABLE 8
Backplane and multi-level metallization structure.

Lamination with a prepreg
Monolithic isle (icell) cut
Silicon etch back
Texture and drying
Front passivation
Via drill through prepreg to access Metal 1
Metal 2 deposition and isolation (example: PVD/plating)
Anneal if needed

Fabrication processes shown in Table 8 include laminating a backplane (e.g., prepreg) to a thicker cell, thinning the silicon absorber while it is held and supported by the backplane (e.g., prepreg), texturing the silicon absorber and applying front passivation. Subsequently, laser holes are drilled in the backplane (e.g., prepreg), for example backplane 14 shown in FIG. 1B, to access and stop on metal 1 (e.g., first level metal such as cell emitter 10 and cell base metal 12 shown in FIGS. 1A and 1B) and deposit and pattern metal 2 (e.g., second emitter metal 16 and second base metal 18 shown in FIG. 1B).

Solar cell frontside (sunnyside) passivation may be formed with aluminum oxide Al2O3 which has the advantageous features of: providing very low surface recombination velocities, for example less than 10 cm/s; not absorbing readily in the visible spectrum, making it maximally transparent to the wavelengths which form useful electric current; may be stable against UV radiation and meet long term solar cell field reliability requirements.

In some instances, aluminum oxide need a slightly elevated temperature of approximately 300 to 400° C. This elevated temperature may make is necessary to ensure amorphous silicon passivations are either stable during this elevated temperature process or are deposited after Al2O3 films are deposited and activated.

Amorphous silicon passivation may also be used on the solar cell frontside (sunnyside). Amorphous silicon frontside passivation may suffer from light induced degradation, however, if an indium tin oxide ITO layer is used as an anti-reflection coating ARC it may substantially cut down the deleterious UV on the amorphous silicon frontside passivation.

Additional variations of the backside processes are possible, including but not limited to, switching the process order between different process steps such as performing a monolithic isle (icell) cut after the silicon etchback step and then performing a texture.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A method for making a passivated surface and base and emitter regions in a silicon substrate, comprising:
forming intrinsic amorphous silicon on a first surface of a silicon substrate;
forming a first dopant on said intrinsic amorphous silicon;
applying first laser beam through said first dopant and forming at least a first doped region in said silicon substrate having the polarity of said first dopant;
forming a second dopant on said intrinsic amorphous silicon; and
applying second laser beam through said second dopant and forming at least a second doped region in said silicon substrate having the polarity of said second dopant.

2. The method of claim 1, wherein said intrinsic amorphous silicon has a thickness greater than 10 nm.

3. The method of claim 1, wherein said intrinsic amorphous silicon is amorphous SiCx.

4. The method of claim 1, wherein said intrinsic amorphous silicon is amorphous SiOx.

5. The method of claim 1, wherein said intrinsic amorphous silicon is amorphous SiNx.

6. The method of claim 1, wherein said first dopant is a doped amorphous silicon.

7. The method of claim 1, wherein said first dopant is a spin on dopant.

8. The method of claim 1, wherein said first dopant is a patterned printed dopant.

9. The method of claim 1, wherein said first laser beam has a green wavelength.

10. A method for making a passivated surface and base and emitter regions in a silicon substrate, comprising:
forming intrinsic amorphous silicon on a first surface of a silicon substrate, said intrinsic amorphous silicon having a thickness greater than 10 nm;
forming doped amorphous silicon on a first surface of a silicon substrate, said doped amorphous silicon having a thickness greater than 10 nm;
opening windows to said intrinsic amorphous silicon in a doping pattern;
forming a dopant on said intrinsic amorphous silicon; and
applying laser beam through said dopant and said doped amorphous silicon and forming at least a first doped region in said silicon substrate having the polarity of said dopant and at least a second doped region in said silicon substrate having the polarity of said doped amorphous silicon.

11. The method of claim 9, wherein after said laser beam is applied through said dopant and forming at least a first doped region in said silicon substrate having the polarity of said dopant said first dopant is removed and a laser beam is applied through said doped amorphous silicon and forming at least a second doped region in said silicon substrate having the polarity of said doped amorphous silicon.
